(19) United States
(12) Patent Application Publication
(10) Pub. No.: US 2008/0232061 A1
(43) Pub. Date: Sep. 25, 2008

(54) Portable Electronic System

(75) Inventors: Hui-Chen Wang, Taipei (TW); Kun-Huang Hsu, Taipei (TW); Wei-Huan Chou, Taipei (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: ASUSTEK COMPUTER INC., Taipei (TW)

(21) Appl. No.: 12/048,435

(22) Filed: Mar. 14, 2008

(30) Foreign Application Priority Data
Mar. 21, 2007 (TW) 96109761

(51) Int. Cl. H05K 7/00

(52) U.S. Cl. 361/686

(57) ABSTRACT

A portable electronic system including a body and a dock is described. The body has a waterproof first connector and a first attracting portion, wherein the first connector has a plurality of electrical terminals. The dock has a second connector and a second attracting portion, wherein the second connector has a plurality of retractable pogo pins. When the body is placed on the dock to make the first connector connected to the second connector, the magnetic force between the second attracting portion and the first attracting portion makes the electrical terminals compress the retractable pogo pins to a critical distance to achieve the electrical connection between the body and the dock.

### RELATED APPLICATIONS

This application claims priority to Taiwan Application Serial Number 96109761, filed Mar. 21, 2007, which is herein incorporated by reference.

### BACKGROUND OF THE INVENTION

1. Field of the Invention

The invention relates to a portable electronic system and, more particularly, to a portable electronic system with a pogo pin connector.

2. Description of the Related Art

Nowadays, a portable computer device often needs to be connected to a dock for charging or exchanging the information between another electronic device or a peripheral device. If the body of the portable computer device is waterproof by demand, the dock often equips a waterproof pogo pin connector with retractable pogo pins. The retractable pogo pins of the connector electrically connect to the dock only when the retractable pogo pins are compressed in a critical distance by the body of the portable computer device. Moreover, the critical distance is different for various standards.

Besides, the body of the computer device needs enough weight to compress the pogo pins in a critical distance, thus to make the body electrically connected to the dock. Currently, the body of the computer device has the trend of light weight, slim, short and small dimensions for readily carrying. However, the weight of the body might be too light to compress the pogo pin connector on the dock to a critical distance efficiently. Hence the electrical connection between the body and the dock cannot be achieved.

### BRIEF SUMMARY OF THE INVENTION

A preferred embodiment of the invention provides a portable electronic system, and the electrical connection structure disposed between the body and the dock can effectively connect the pogo pin connector and make the electrical connection effectively.

According to a portable electronic system including a body and a dock of a preferred embodiment of the invention, the body has a waterproof first connector and a first attracting portion, wherein the first connector has a plurality of electrical terminals. The dock has a second connector and a second attracting portion, the second connector has a plurality of retractable pogo pins. When the body is placed on the dock to connect the first connector with the second connector, the magnetic force attracts the second attracting portion and the first attracting portion. The electrical terminal compresses the retractable pogo pins to a critical distance and the electrical connection between the body and the dock is thus achieved.

The first attracting portion of the body can be a magnet or magnetic material. The second attracting portion of the dock can be a magnet or magnetic material.

The dock further includes a adapting recess for holding the second connector and the second attracting portion. The dock further includes a control device to monitor the connecting state of the first connector and the second connector.

According to the preferred embodiment of the invention, the control device includes a control knob and a control rod. The control knob is preferred to be exposed on the dock. The control rod is preferred to connect the control knob and the second attracting portion. The control knob and control rod connects the dock to control the distance between the second attracting portion and the first attracting portion in a sliding way.

According to another preferred embodiment of the invention, the control device includes a control knob and a control rod. The control knob is exposed on the dock. The control rod connects the control knob and the second attracting portion. The control knob and the control rod connects the dock to control the second attracting portion in a rotating way, thus to switch the state of attracting state or repelling state between the first attracting portion and the second attracting portion by rotating.

The portable electronic system of the invention utilizes the magnetism principle as connecting force between the connectors. The control device is beneficial to make the connectors separate from each other easily for a user use it conveniently.

These and other features, aspects, and advantages of the present invention will become better understood with regard to the following description, appended claims, and accompanying drawings.

### BRIEF DESCRIPTION OF THE DRAWINGS

FIG. 1 is a partial enlarged diagram showing a body and a device connector of a portable electronic system according to a preferred embodiment of the invention;

FIG. 2 is a partial enlarged diagram showing a dock and a dock connector of a portable electronic system according to a preferred embodiment of the invention.

FIG. 3 is a schematic diagram showing the connection between the body and the dock of a portable electronic system according to a preferred embodiment of the invention;

FIG. 4 is a first manner for separating the body of the a portable electronic system from the dock of a preferred embodiment of the invention; and

FIG. 5 is a second manner for separating the body of a portable electronic system from the dock of a preferred embodiment of the invention.

### DETAILED DESCRIPTION OF THE EMBODIMENTS

As stated above, the invention provides a portable electronic system. The following embodiment further describes the detail of the invention.

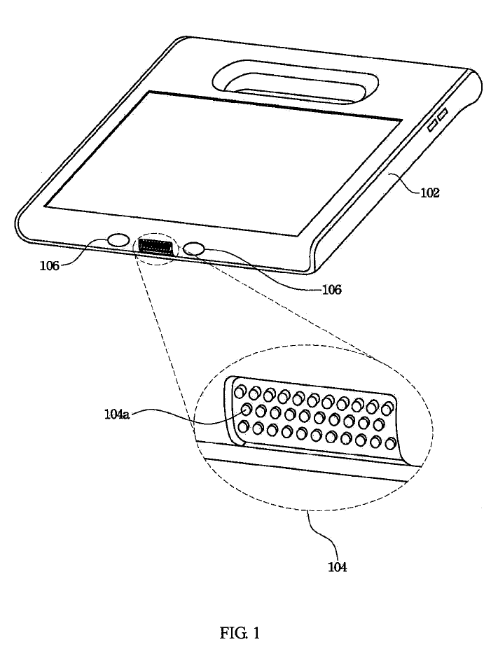

Please refer to FIG. 1, which shows the body structure of a portable electronic system according to a preferred embodiment of the invention. The body 102 has a waterproof device connector 104 which is composed of a plurality of electrical terminals 104a.

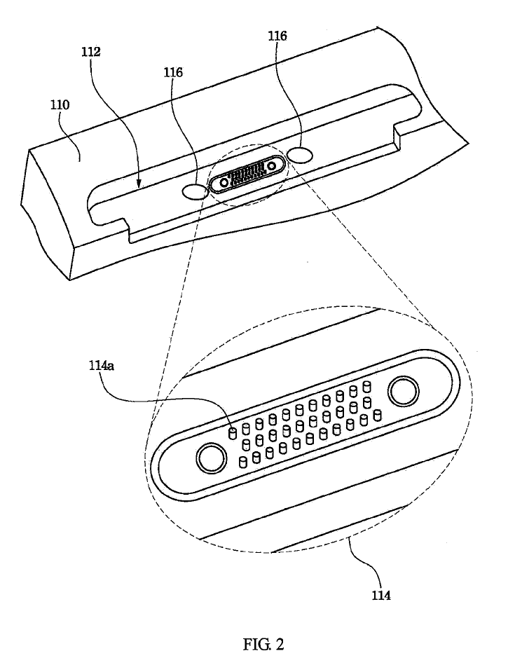

Please refer to FIG. 2, which shows the dock structure of a portable electronic system according to a preferred embodiment of the invention. A dock 110 cooperating with an electronic device has a dock connector 114 composed of a plurality of retractable pogo pins 114a. Since the dock connector 114 has springs for supporting the pogo pins 114a, the pogo pins 114a can be compressed or decompressed. In addition, the pogo pins 114a of the dock connector 114 have the function of electrical connection only when it is compressed to a critical distance.

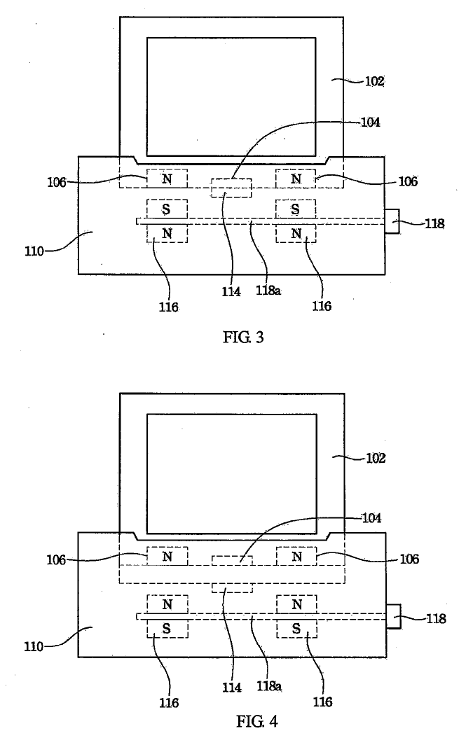

FIG. 3 is a schematic diagram showing the connection between the body and the dock of the portable electronic system. Please refer to FIG. 1, FIG. 2, and FIG. 3. When the body 102 is placed on the dock 110 to connect the device connector 104 to the dock connector 114, the body 102 should be fastened at the adapting recess 112 of the dock 110. At this moment, the plurality of electrical terminals 104a of the device connector 104 contacts the pogo pins 114a of the dock connector 114. The magnetic force between the device attracting portion 106 and the dock attracting portion 116 makes the electrical terminals 104a to compress the corresponding pogo pins 114a in excess of a critical distance, thus to achieve the electrical connection between the body 102 and the dock 110. For different pogo pin connectors, the critical distance is various. The device attracting portion 106 and the dock attracting portion 116 can be magnets or magnet materials (such as cobalt, iron, nickel and so on).

When a user wants to separate the body 102 of the portable electronic system from the dock 110, the easiest way is to pull the body 102 directly by applying a force to separate it from the dock 110. However, as for some users (such as female users), the way above is sometimes inconvenient. Therefore, a control device can be provided at the dock 110 to make the body 102 separate from the dock 110 easily. FIG. 4 is a schematic diagram showing a control device for separating the body of the portable electronic system from the dock.

Please refer to FIG. 3 and FIG. 4. In the embodiment, the control device includes control knob 118 and control rod 118a. The control knob 118 and the control rod 118a are connected to the dock 110 in a rotating manner. The control knob 118 is exposed on the dock 110 for a user to rotate. The control rod 118a is connected to the control knob 118, and the dock attracting portion 116 is fixed at the control rod 118a. When a user rotates the control knob 118, the state of attracting (N-S contact) or repelling (N-N contact) between the device attracting portion 106 and the dock attracting portion 116 can be switched.

When the body 102 is placed at the dock 110 to connect the device connector 104 with the dock connector 114, the device attracting portion 106 and the dock attracting portion 116 are in an attracting state (as the state shown in FIG. 3). When a user wants to separate the body 102 of the portable electronic system from the dock 110, the control knob 118 can be rotated to switch the state between the device attracting portion 106 and the dock attracting portion 116 to a repelling state (as the state shown in FIG. 4). At this moment, the body 102 will be ejected by the repellent magnetic force and the retractable pogo pins 114a, so that a user can take the body 102 out of the dock 110 easily.

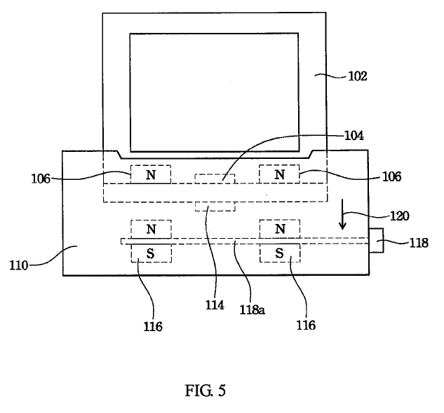

FIG. 5 shows a schematic diagram showing another control device for separating the body of the portable electronic system from the dock. Please refer to FIG. 3 and FIG. 4. Besides the manner described above, the invention also provides another manner to separate the body 102 from the dock 110. This manner also needs a control device provided at the dock 110 to make the body 102 separate from the dock 110 easily. The control device includes a control knob 118 and the control rod 118a, and the control knob 118 and the control rod 118a is connected to the dock 110 in a sliding manner to control the distance between the dock attracting portion 116 and the device attracting portion 106. The control knob 118 is exposed on the dock 110 for a user to apply a force. The control rod 118a is connected to the control knob 118, and the dock attracting portion 116 is fixed at the control rod 118a.

When the body 102 is placed on the dock 110 to connect the device connector 104 to the dock connector 114, the distance between the device attracting portion 106 and the dock attracting portion 116 is small (as the state shown in FIG. 3), so that the magnetic force attraction is sufficient to connect the device connector 104 to the dock connector 114 and performs electrical connection. When a user wants to separate the body 102 of the portable electrical system from the dock 110, a force can be applied on the control knob 118 along the direction 120 to make the distance between the dock attracting portion 116 and the device attracting portion 106 greater (as the stated shown in FIG. 5), so that the magnetic force attraction is not sufficient to connect the device connector 104 to the dock connector 114. At that moment, the body 102 can be ejected by the retractable pogo pins 114a, and a user can take the body 102 out of the dock 110 easily.

From the preferred embodiment of the invention, the principle of magnetism is used for the demand of connecting the connectors with pogo pin connector of the invention. The control device is also disclosed for the connectors separated from each other more easily.

Although the present invention has been described in considerable detail with reference to certain preferred embodiments thereof, the disclosure is not for limiting the scope of the invention. Persons having ordinary skill in the art may make various modifications and changes without departing from the scope of the invention. Therefore, the scope of the appended claims should not be limited to the description of the embodiments described above.

What is claimed is:

1. A portable electronic system comprising:
a body having a waterproof first connector and a first attracting portion, wherein the first connector has a plurality of electrical terminals; and
a dock having a second connector and a second attracting portion, wherein the second connector has a plurality of retractable pogo pins;
wherein when the body is placed on the dock to make the first connector connect the second connector, the second attracting portion and the first attracting portion attracts each other by magnetic force, the electrical terminals compresses the retractable pogo pins to a critical distance to make the body electrically connect to the dock.

2. The portable electronic system according to claim 1, wherein the first attracting portion is a magnetic material.

3. The portable electronic system according to claim 1, wherein the second attracting portion is a magnetic material.

4. The portable electronic system according to claim 1, wherein the first attracting portion is a magnet.

5. The portable electronic system according to claim 1, wherein the second attracting portion is a magnet.

6. The portable electronic system according to claim 1, wherein the dock further comprises a adapting recess, and the second connector and the second attracting portion are provided in the adapting recess.

7. The portable electronic system according to claim 1, wherein the dock further comprises a control device.

8. The portable electronic system according to claim 7, wherein the control device comprises:
a control knob exposed on the dock; and
a control rod connect the control knob and the second attracting portion,
wherein the control knob and the control rod connect the dock in a sliding manner.

9. The portable electronic system according to claim 7, wherein the control device comprises:
a control knob exposed on the dock; and
a control rod connect the control knob and the second attracting portion,
wherein the control knob and the control rod connect the dock in a rotating manner.
